(19) United States
(12) Patent Application Publication
(10) Pub. No.: US 2025/0314485 A1
(43) Pub. Date: Oct. 9, 2025

(54) BROADBAND CALIBRATION SENSOR HEAD

(71) Applicant: Raytheon Company, Tewksbury, MA (US)

(72) Inventors: James Wedell, Tucson, AZ (US); Scott K. Smith, Marana, AZ (US); Jose D. Mendoza, Tucson, AZ (US); Eric J. Nill, Vail, AZ (US); Robert E. Munger, Sonoita, AZ (US); Edgar G. Ortiz, Tucson, AZ (US)

(21) Appl. No.: 18/628,498

(22) Filed: Apr. 5, 2024

(51) Int. Cl. G01B 15/00; G01B 11/27

(52) U.S. Cl. CPC G01B 15/00; G01B 11/27

(57) ABSTRACT

An apparatus for testing an antenna element of an antenna array includes a laser configured to generate a laser beam for coarse mechanical positioning of the antenna element. The apparatus also includes an interferometer having a plurality of antennas configured to receive signals from the antenna element for fine electrical positioning of the antenna element, where the laser and the interferometer are collocated. The apparatus further includes a controller configured to control positioning of the laser and the interferometer based on information associated with the laser beam received by the controller and the signals received from the antenna element.

### TECHNICAL FIELD

This disclosure generally relates to antenna alignment systems. More specifically, this disclosure relates to a broadband calibration sensor head (B-CSH) for alignment of an antenna element of an antenna array.

### BACKGROUND

Various antenna alignment systems may provide both mechanical and electrical alignment of antenna(s) on a structure so as to place the antenna(s) onto a projected hemispherical surface. For example, antenna alignment systems support locating antenna mounting positions and electrical phase centers and support angular positioning.

### SUMMARY

This disclosure relates to a calibration sensor head for supporting mechanical and electrical alignment of antenna elements of an antenna array.

In a first embodiment, an apparatus for testing an antenna element of an antenna array includes a laser configured to generate a laser beam for coarse mechanical positioning of the antenna element. The apparatus also includes an interferometer having a plurality of antennas configured to receive signals from the antenna element for fine electrical positioning of the antenna element, where the laser and the interferometer are collocated. The apparatus further includes a controller configured to control positioning of the laser and the interferometer based on information associated with the laser beam received by the controller and the signals received from the antenna element.

In a second embodiment, a system for testing an antenna element of an antenna array includes a laser system having a laser configured to generate a laser beam for coarse mechanical positioning of the antenna element. The system also includes an interferometer system having a plurality of antennas configured to receive signals from the antenna element for fine electrical positioning of the antenna element, including a removable center antenna. The laser and the interferometer are collocated. The system further includes a controller configured to control positioning of the laser and the interferometer based on information associated with the laser beam received by the controller and the signals received from the antenna element.

In a third embodiment, a method for testing an antenna element of an antenna array includes generating a laser beam. The method also includes receiving information associated with the laser beam for coarse mechanical positioning of the antenna element. The method further includes receiving, via an interferometer, signals from the antenna element for fine electrical positioning of the antenna element, where the laser and the interferometer are collocated. In addition, the method includes positioning the laser and the interferometer based on the received information associated with the laser beam and the signals received from the antenna element.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example calibration sensor head for supporting mechanical and electrical alignment of antenna elements in accordance with this disclosure;

FIG. 2 illustrates an example interferometer having a removable center antenna for supporting mechanical and electrical alignment of antenna elements in accordance with this disclosure;

FIG. 3 illustrates an example architecture supporting use of a calibration sensor head for supporting mechanical and electrical alignment of antenna elements in accordance with this disclosure;

FIG. 4 illustrates an example architecture supporting application of a laser for coarse positioning and alignment of antenna elements and an interferometer for fine positioning and alignment of the antenna elements in accordance with this disclosure;

FIG. 5 illustrates an example architecture supporting use of a calibration sensor head for supporting mechanical and electrical alignment of antenna elements in accordance with this disclosure;

FIG. 6 illustrates an example architecture supporting use of a calibration sensor head for supporting spherical alignment of antenna elements in accordance with this disclosure; and

FIG. 7 illustrates an example power and control architecture supporting use of a calibration sensor head for supporting mechanical and electrical alignment of antenna elements in accordance with this disclosure.

### DETAILED DESCRIPTION

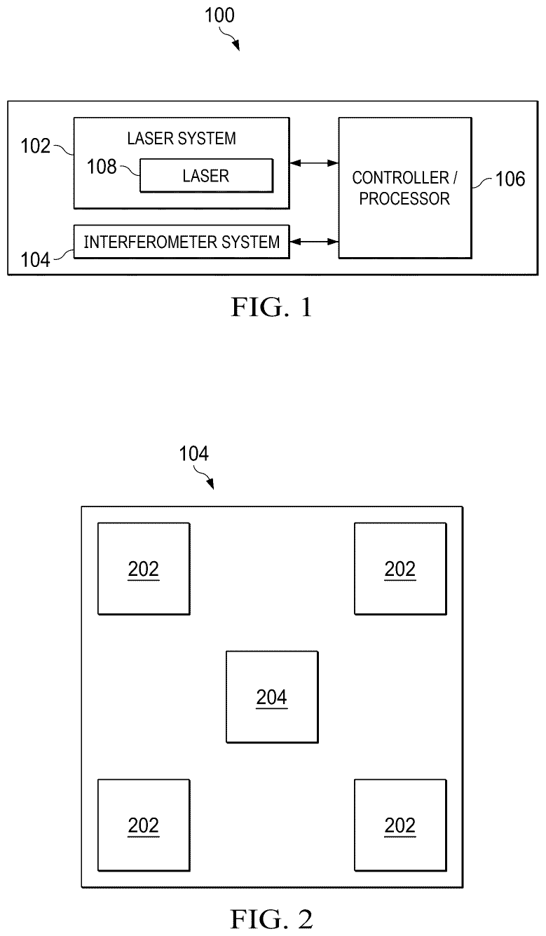

FIGS. 1 through 7, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, various antenna alignment systems may provide both mechanical and electrical alignment of antenna(s) so as to place the antenna(s) onto a projected hemispherical surface. When multiple antennas are aligned, they are electrically positioned on this projected hemispherical surface and will radiate collimated electromagnetic energy.

The focal point of this collimated electromagnetic energy is the pivot point of the apparatus providing attitude adjustments. As the measurement device is positioned on the apparatus and is offset from the pivot point, measurements are made on the resulting hemispherical surface, which is concentric to the projected hemispherical surface of the array.

The utility of this process is for hemispherical alignment of antennas that include discrete antennas or subarray elements. Good spherical alignment of array elements is advantageous for optimal beamforming, direction of arrival, and to minimize polarization and mismatch losses.

Unfortunately, separate test fixtures are needed for mechanical and electrical alignment of the antennas, which causes added down time needed to mount/unmount the separate text fixtures. In addition, the use of separate text fixtures increases the likelihood of mounting skew errors between the text fixtures, which also increases the likelihood for measurement error.

Accordingly, embodiments of this disclosure provide various techniques for supporting mechanical and electrical alignment of antenna elements using a calibration sensor head that includes a laser and an interferometer in a single device. In addition to the time and cost savings associated with consolidating the laser and interferometer into a single device, the measurement error can also be reduced due to a common motion platform interface.

As described in more detail below, mechanical and electrical alignment of antenna elements may be performed using a calibration sensor head that includes a laser and an interferometer in a single device. For example, mechanical and electrical alignment of antenna elements may be performed using a calibration sensor head that includes a laser configured to generate a laser beam for coarse mechanical positioning of the antenna element, and an interferometer configured to receive signals from the antenna element for fine electrical positioning of the antenna element. Mechanical alignment of the antenna element may be determined based on the projection of the laser beam onto a target cover of the antenna element, or based on light reflected by a mirror on the antenna element from the projection of the generated laser beam. Electrical alignment of the antenna element may be determined by calculating an angle of arrival of the signals received from the antenna element, calculating a relative group delay of the signals received from the antenna element, or calculating a polarization orientation of the signals received from the antenna element. Adjustments to the mechanical and electrical alignment of the antenna element can be made based on the alignment determinations.

Note that the described techniques for supporting mechanical and electrical alignment of antenna elements using a calibration sensor head that includes a laser and an interferometer in a single device may be used in any suitable manner and in any suitable application. In the following discussion, it is often assumed that the described techniques for supporting mechanical and electrical alignment of antenna elements using a calibration sensor head that includes a laser and an interferometer in a single device are used with a concentric laser and a broadband RF interferometer. However, the described techniques for supporting mechanical and electrical alignment of antenna elements using a calibration sensor head that includes a laser and an interferometer in a single device may be used in any other suitable systems and with any other suitable laser and interferometer. In general, this disclosure is not limited to use in any specific type(s) of system(s) or with any specific type(s) of laser or interferometer.

FIG. 1 illustrates an example calibration sensor head 100 for supporting mechanical and electrical alignment of antenna elements in accordance with this disclosure. The embodiment of the calibration sensor head 100 for supporting mechanical and electrical alignment of antenna elements illustrated in FIG. 1 is for illustration only. FIG. 1 does not limit the scope of this disclosure to any particular implementation of the calibration sensor head 100 for supporting mechanical and electrical alignment of antenna elements.

As shown in FIG. 1, the calibration sensor head 100 includes a laser system 102 including a laser 108, an interferometer system 104, and a controller/processor 106 operably coupled to the laser system 102 and the interferometer system 104. The laser system 102 and the interferometer system 104 are collocated.

The laser system 102 can be used for coarse angular positioning of each antenna element, at specific coordinates. The laser system 102 includes a laser 108 that may generate a concentric, collimated beam, and can be used to project light for mechanical positioning, such as mounting positions of the antenna element, and to project light where reflection of the projected light is used for mechanical attitude adjustments.

The interferometer system 104 can be used for fine positioning and alignment of each antenna element, such as an electrical phase center of the antenna element. In some embodiments, the interferometer system 104 may include a two-dimensional interferometer comprising four single linear polarization antennas in equal-leg cruciform configuration and a center antenna at the centroid of the cruciform. The four polarization antennas may be disposed around the perimeter of the calibration sensor head 100. The four polarization antennas support interferometric fine angular positioning, based upon the electrical phase center of each antenna element. The central antenna is removable, and when installed may be utilized for path length adjustment for each antenna element. The central antenna may also be utilized for measuring dual-pol magnitude and phase calibration factors for each antenna element.

In other embodiments, the interferometer system 104 may include a one-dimensional interferometer and dual-linear polarized antennas. In yet other embodiments, the interferometer system 104 may include a two-dimensional interferometer and dual-linear polarized antennas.

The controller/processor 106 is operably coupled to the laser system 102 and to the interferometer system 104. The controller/processor 106 is configured to control positioning of the laser system 102 and the interferometer system 104 so as to facilitate alignment and attitude adjustments of the antenna elements.

The controller/processor 106 can include one or more processors or other processing devices that control the overall operation of the calibration sensor head 100. For example, the controller/processor 106 could support the antenna alignment process, in which reflected light projected from the laser system 102 is received and signals from the antenna element to be aligned are received by the interferometer system 104. A variety of other functions could be supported in the calibration sensor head 100 by the controller/processor 106.

The controller/processor 106 is also capable of executing programs and other processes resident in a memory, such as processes for supporting application of the laser system 102 for mechanical alignment and application of the interferometer system 104 for electrical alignment. The controller/processor 106 can move data into or out of the memory as required by an executing process.

FIG. 2 illustrates an example interferometer system 104 of FIG. 1 having a removable center antenna for supporting mechanical and electrical alignment of antenna elements in accordance with this disclosure. The embodiment of the interferometer system 104 of FIG. 1 having a removable center antenna for supporting mechanical and electrical alignment of antenna elements illustrated in FIG. 2 is for illustration only. FIG. 2 does not limit the scope of this disclosure to any particular implementation of the interferometer system 104 of FIG. 1 having a removable center antenna for supporting mechanical and electrical alignment of antenna elements.

As shown in FIG. 2 and as described above, the interferometer system 104 may include four single linear polarization antennas 202 in equal-leg cruciform configuration and a center antenna 204 at the centroid of the cruciform. The four polarization antennas 202 may be disposed around the perimeter of the calibration sensor head 100. The four polarization antennas 202 support interferometric fine angular positioning, based upon the electrical phase center of each antenna element. For example, the four polarization antennas may support pitch and yaw adjustments of the antenna element. The central antenna 204 is removable, and when installed may be utilized for path length adjustment for each antenna element. The central antenna element 204 may also be utilized for measuring dual-pol magnitude and phase calibration factors for each antenna element.

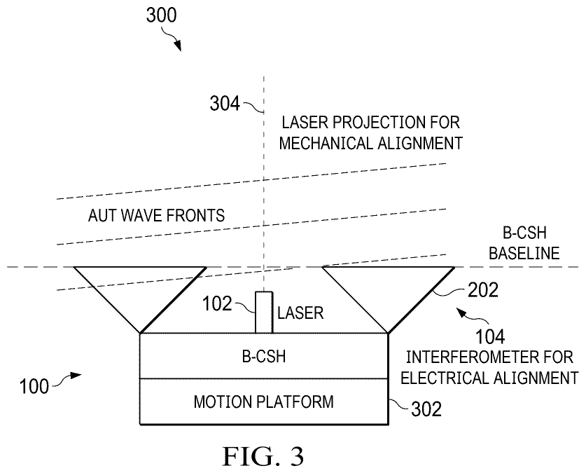

FIG. 3 illustrates an example architecture 300 supporting use of a calibration sensor head for supporting mechanical and electrical alignment of antenna elements in accordance with this disclosure. The embodiment of the example architecture 300 supporting use of a calibration sensor head for supporting mechanical and electrical alignment of antenna elements illustrated in FIG. 3 is for illustration only. FIG. 3 does not limit the scope of this disclosure to any particular implementation of the example architecture 300 supporting use of a calibration sensor head for supporting mechanical and electrical alignment of antenna elements.

As shown in FIG. 3, the architecture 300 includes the calibration sensor head 100 of FIG. 1, including the laser system 102 and the interferometer system 104. The interferometer system 104 includes antennas, such as the antennas 202 of FIG. 2, for receiving radio waves from the antenna element. The architecture 200 includes a motion platform 302 operably coupled to the calibration sensor head 100. The motion platform is configured to provide motion to the calibration sensor head 100 to obtain orthogonal polarization measurements. The motion platform in this example provides motion in three degrees of freedom (such as pitch, yaw, and roll angle) to support attitude adjustments of the antenna element to be aligned, and to support radio frequency measurements after antenna alignment, for use in characterization and compensation of gain, phase, power, and polarization of radiated signals from the antenna element. In this example, the motion platform 302 is external to the calibration sensor head 100. However, the motion platform 302 may be integrated with the calibration sensor head 100.

In operation, the laser system 102 produces a beam 304 for mechanical positioning of the antenna element. The mechanical positioning may include using the laser system 102 for projecting where on an array to make a cutout so as to install the antenna element. The beam 304 may be pointed at a location by setting the motion platform 302 to a specified pitch, yaw, and roll angle. The mechanical positioning may also include using the laser system 102 for projecting the beam 304 such that reflected light from the beam 304 projected from the laser system 102 is received by the calibration sensor head 100 and used to determine attitude misalignment (pitch and yaw). Adjustments to the antenna mount of the antenna element being aligned may be made to collocate the reflection within the source.

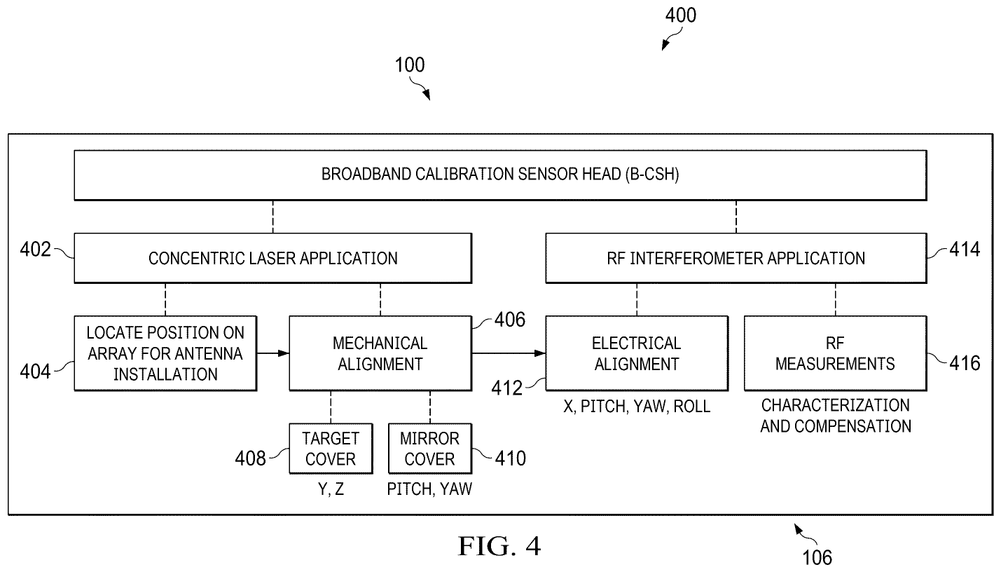

FIG. 4 illustrates an example architecture 400 supporting application of a laser for coarse positioning and alignment of antenna elements and an interferometer for fine positioning and alignment of the antenna elements in accordance with this disclosure. The embodiment of the example architecture 400 supporting application of a laser for coarse positioning and alignment of antenna elements and an interferometer for fine positioning and alignment of the antenna elements illustrated in FIG. 4 is for illustration only. FIG. 4 does not limit the scope of this disclosure to any particular implementation of the example architecture 400 supporting application of a laser for coarse positioning and alignment of antenna elements and an interferometer for fine positioning and alignment of the antenna elements.

As shown in FIG. 4, the architecture 400 includes the calibration sensor head 100 of FIG. 1, including the controller/processor 106. The controller/processor 106 includes processes resident in a memory (not shown), such as a process 402 for supporting application of the laser system 102 of FIG. 1 for mechanical alignment of the antenna element and a process 414 for supporting application of the interferometer system 104 of FIG. 1 for electrical alignment of the antenna element and RF measurements.

As described above, the laser system 102 of FIG. 1 can be used for coarse angular positioning of each antenna element, at specific coordinates. The process 402 for supporting application of the laser system 102 of FIG. 1 for mechanical alignment of the antenna element may include a process 404 for locating a position on the antenna array for installation of the antenna element, and a process 406 for mechanical alignment of the antenna element. The process 404 for locating a position on the antenna array for installation of the antenna element may include the laser system 102 of FIG. 1 generating a concentric, collimated beam (such as the beam 304 of FIG. 3) that can be pointed at a location on an array to make a cutout so as to install the antenna element. The process 404 may include the beam 304 being pointed at a location by setting a motion platform (such as the motion platform 302 of FIG. 3) to a specified pitch, yaw, and roll angle.

In some embodiments, the process 406 for mechanical alignment of the antenna element may include the use of a target cover 408 installed on the face of the antenna element to be aligned. The process my include projecting the beam 304 onto the target cover 408. Adjustments to the antenna mount of the antenna element being aligned may be made to adjust the alignment along the Y and Z axes of the antenna element being aligned until projection is centered on the target cover. The process 406 may include the beam 304 being pointed at a location by setting a motion platform (such as the motion platform 302 of FIG. 2) to a specified pitch, yaw, and roll angle.

In some embodiments, the process 406 for mechanical alignment of the antenna element includes the use of a mirror cover 410 installed on the face of the antenna element to be aligned. The process includes projecting the beam 304 onto the mirror cover 410 such that reflected light from the beam 304 projected from the laser system 102 is received by the calibration sensor head 100 and used to determine attitude misalignment (pitch and yaw). Adjustments to the antenna mount of the antenna element being aligned may be made to collocate the reflection within the source.

The process 414 for supporting application of the interferometer system 104 of FIG. 1 for electrical alignment of the antenna element and RF measurements may include a process for electrical alignment 412 and a process for RF measurements 416. In some embodiments, the process for electrical alignment 412 may include receiving a signal radiated from the antenna element to be aligned, and calculating an angle of arrival of the radiated signal. The calculated angle of arrival may be used to make attitude adjustments to the antenna mount of the antenna element being aligned. The process 414 may include pointing the calibration sensor head 100 to a specified pitch, yaw, and roll angle by setting a motion platform (such as the motion platform 302 of FIG. 3) to a specified pitch, yaw, and roll angle.

In some embodiments, the process for electrical alignment 412 may include utilizing the removable center antenna 204 of the interferometer system 104. The process for electrical alignment 412 may include receiving a signal radiated from the antenna to be aligned, and calculating a polarization orientation of the signal radiated from the antenna element to be aligned. The calculated polarization orientation may be used to make roll adjustments to the antenna mount of the antenna element to be aligned.

In some embodiments, the process for electrical alignment 412 may include utilizing the removable center antenna of the interferometer system 104. The process for electrical alignment 412 may include receiving signals radiated from the antenna to be aligned, and calculating a relative group delay of the received signals. The calculated relative group delay may be used to adjust the antenna mount of the antenna element to be aligned along its X axis.

In some embodiments, the process for electrical alignment 412 may include collecting two data sets with the calibration sensor head 100 inverted on the second data set. In other words an initial data set is collected, the calibration sensor head 100 is then rolled 180 degrees (inverting the antennas of the interferometer system 104) and a second data set is collected. These two sets of data are then combined via post processing. Through this process, the path errors for the individual antennas are cancelled out, yielding a very precise measurement result.

In some embodiments, the process 418 for RF measurements may include utilizing the removable center antenna of the interferometer system 104. The process 418 for RF measurements may include receiving signals radiated from the antenna to be aligned, and measuring characteristics of the received signals. The measured characteristics may be used for aligning, compensating, equalizing, and verifying elements of analog signal generation and signal presentation hardware. The process 418 may include pointing the calibration sensor head 100 to a specified pitch, yaw, and roll angle by setting a motion platform (such as the motion platform 302 of FIG. 3) to a specified pitch, yaw, and roll angle.

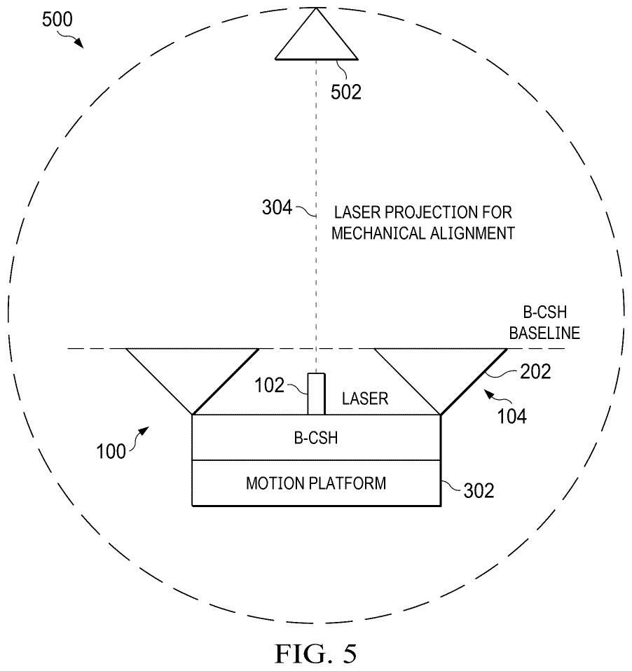

FIG. 5 illustrates an example architecture 500 supporting use of a calibration sensor head for supporting mechanical and electrical alignment of antenna elements in accordance with this disclosure. The embodiment of the example architecture 500 supporting use of a calibration sensor head for supporting mechanical and electrical alignment of antenna elements illustrated in FIG. 5 is for illustration only. FIG. 5 does not limit the scope of this disclosure to any particular implementation of the example architecture 500 supporting use of a calibration sensor head for supporting mechanical and electrical alignment of antenna elements.

As shown in FIG. 5, the architecture 500 includes the calibration sensor head 100 of FIG. 1 including the laser system 102 and the interferometer system 104, the antennas 202 of FIG. 2, the motion platform 302 and the beam 304 of FIG. 3, and an antenna element 502. As described above, the laser system 102 can be used for coarse angular positioning of each antenna element at specific coordinates, and the interferometer system 104 can be used for fine positioning and alignment of each antenna element, such as an electrical phase center of the antenna element. The laser system 102 can generate the beam 304 that can be pointed at a location on an array to make a cutout so as to install the antenna element 502. The beam 304 may be pointed at the location on the array by setting the motion platform 302 to a specified pitch, yaw, and roll angle. The interferometer system 104 may receive a signal radiated from the antenna element 502 to be aligned, and calculate an angle of arrival of the radiated signal. The calculated angle of arrival may be used to make attitude adjustments to the antenna mount of the antenna element being aligned.

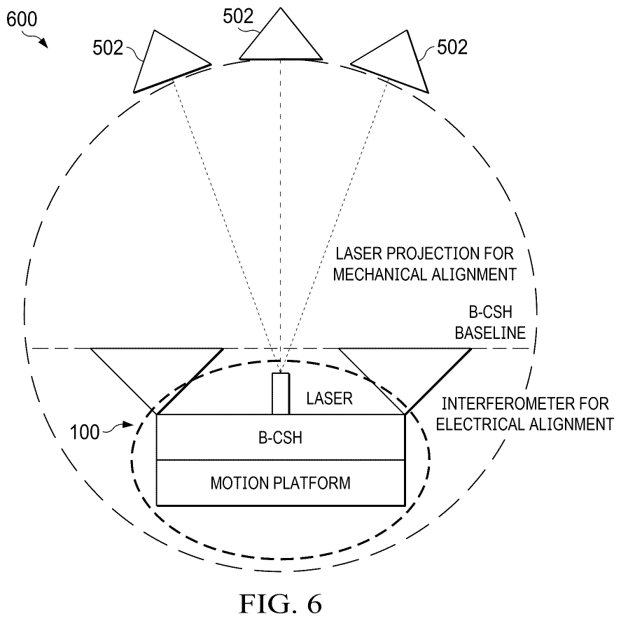

FIG. 6 illustrates an example architecture 600 supporting use of a calibration sensor head for supporting spherical alignment of antenna elements in accordance with this disclosure. The embodiment of the example architecture 600 supporting use of a calibration sensor head for supporting spherical alignment of antenna elements illustrated in FIG. 6 is for illustration only. FIG. 6 does not limit the scope of this disclosure to any particular implementation of the example architecture 600 supporting use of a calibration sensor head for supporting spherical alignment of antenna elements.

As shown in FIG. 6, the architecture 600 includes the calibration sensor head 100 of FIG. 1 including a laser system (such as the laser system 102 of FIG. 1) and an interferometer system (such as the interferometer system 104 of FIG. 1), antennas (such as the antennas 202 and 204 of FIG. 2), a motion platform (such as the motion platform 302 of FIG. 3), a laser projection for mechanical alignment, such as the beam 304 of FIG. 3, and antenna elements (such as the antenna element 502 of FIG. 5).

As described above, when multiple antennas such as the antenna elements 502 are aligned, they are electrically positioned on a projected hemispherical surface and will radiate collimated electromagnetic energy. The focal point of this collimated electromagnetic energy is the pivot point of the apparatus providing attitude adjustments. As the measurement device is positioned on the apparatus and is offset from the pivot point, measurements are made on the resulting hemispherical surface, which is concentric to the projected hemispherical surface of the array. This provides hemispherical alignment of the antenna elements 502, which is advantageous for optimal beamforming, direction of arrival, and to minimize polarization and mismatch losses.

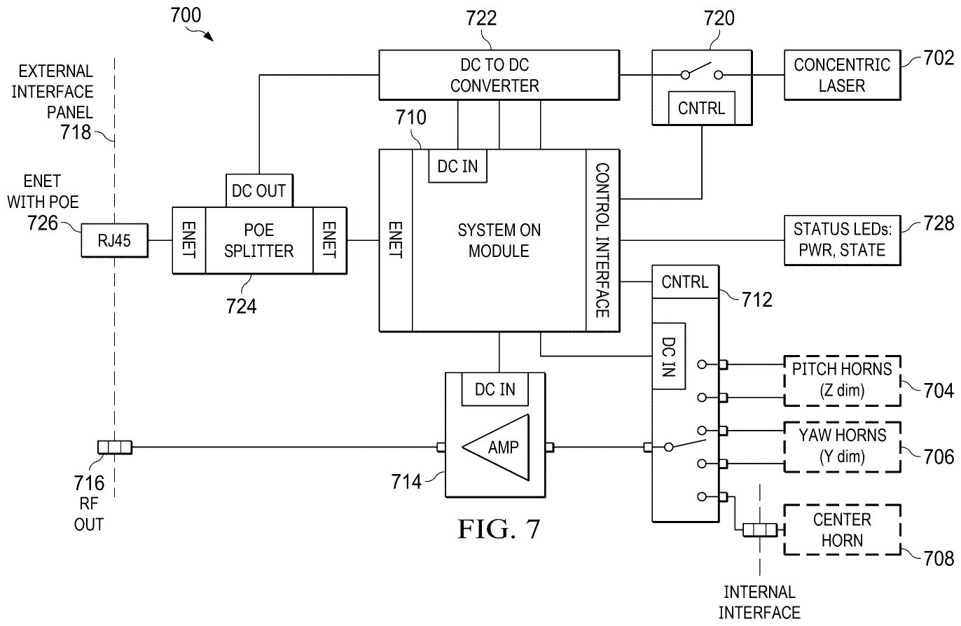

FIG. 7 illustrates an example power and control architecture 700 supporting use of a calibration sensor head for supporting mechanical and electrical alignment of antenna elements in accordance with this disclosure. The embodiment of the example power and control architecture 700 supporting use of a calibration sensor head for supporting mechanical and electrical alignment of antenna elements illustrated in FIG. 7 is for illustration only. FIG. 7 does not limit the scope of this disclosure to any particular implementation of the example power and control architecture 700 supporting use of a calibration sensor head for supporting mechanical and electrical alignment of antenna elements.

As shown in FIG. 7, the architecture 700 includes a laser 702 (such as the laser 108 of FIG. 1), pitch horns 704 (such as the antennas 202 of FIG. 2), yaw horns 706 (such as the antennas 202 of FIG. 2), a removable center horn 708 (such as the removable antenna 204 of FIG. 2), and a system-on-module (SOM) 710 (such as the controller/processor 106 of FIG. 1). As described above, the laser 702 is configured to generate a collimated beam, and can be used to project light for mechanical positioning, such as mounting positions of the antenna element, and to project light where reflection of the projected light is used for mechanical attitude adjustments.

As described above, the pitch horns 704, yaw horns 706, and center horn 708 are configured to receive signals such as radio waves from the antenna element being aligned, and to support interferometric fine angular positioning based upon the electrical phase center of each antenna element. The pitch horns 704, yaw horns 706, and center horn 708 are coupled to a switch 712. The switch 712 is configured to select between the pitch horns 704, yaw horns 706, and center horn 708. The switch 712 is coupled to the SOM 710 and to an amplifier 714. The amplifier 714 may be an RF amplifier configured to amplify signals received by the pitch horns 704, yaw horns 706, and center horn 708. The amplifier 714 is coupled to an RF output 716 that is coupled to an external interface panel 718.

As described above, the SOM 710 is configured to control positioning of the laser 702 and the pitch horns 704, yaw horns 706, and center horn 708 so as to facilitate alignment and attitude adjustments of the antenna elements.

The laser 702 is coupled to a relay 720, such as a power relay. The relay 720 is configured to select the laser 702. The relay 720 is coupled to the SOM 710, and to a DC to DC converter 722 for converting voltage levels. The DC to DC converter is coupled to the SOM 710, and to a power over ethernet (POE) splitter 724 configured to split power from data. The POE splitter 724 is coupled to an RJ45 connector 726 that is coupled to the external interface panel 718. Status LEDs 728 are configured to provide a visual indication of power and control states when the calibration sensor head is in use, and are coupled to the SOM 710.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112 (f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112 (f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus for testing an antenna element of an antenna array, the apparatus comprising:
a laser configured to generate a laser beam for coarse mechanical positioning of the antenna element;
an interferometer comprising a plurality of antennas configured to receive signals from the antenna element for fine electrical positioning of the antenna element, wherein the laser and the interferometer are collocated; and
a controller configured to control positioning of the laser and the interferometer based on information associated with the laser beam received by the controller and the signals received from the antenna element.

2. The apparatus of claim 1, wherein:
the interferometer further comprises a removable center antenna configured to receive the signals from the antenna element to at least one of: measure polarization orientation of the received signals, measure relative group delay of the received signals, or measure radio frequency (RF) characteristics of the received signals;
the plurality of antennas comprises four antennas in equal-leg cruciform configuration; and
the center antenna is disposed at a centroid of the cruciform configuration.

3. The apparatus of claim 2, wherein the controller is configured to:
determine whether the antenna element is mechanically aligned based on the generated laser beam; and
determine whether the antenna element is electrically aligned based on the signals received from the antenna element.

4. The apparatus of claim 3, wherein, to determine whether the antenna element is mechanically aligned, the controller is configured to receive information associated with projection of the generated laser beam onto a target cover of the antenna element to determine misalignment of the antenna element.

5. The apparatus of claim 3, wherein, to determine whether the antenna element is mechanically aligned, the controller is configured to receive information associated with light reflected by a mirror on the antenna element from projection of the generated laser beam to determine misalignment of the antenna element.

6. The apparatus of claim 3, wherein, to determine whether the antenna element is electrically aligned, the controller is configured to calculate an angle of arrival of the signals received from the antenna element to determine attitude misalignment of the antenna element.

7. The apparatus of claim 3, wherein, to determine whether the antenna element is electrically aligned, the controller is configured to calculate a relative group delay of the signals received from the antenna element to determine misalignment in an X-axis of the antenna element.

8. The apparatus of claim 3, wherein, to determine whether the antenna element is electrically aligned, the controller is configured to calculate a polarization orientation of the signals received from the antenna element to determine roll misalignment of the antenna element.

9. The apparatus of claim 3, wherein the controller is further configured to measure characteristics of the signals received from the antenna element to at least one of align, compensate, equalize, or verify elements of the signals received from the antenna element.

10. A system for testing an antenna element of an antenna array, the system comprising:
a laser system comprising a laser configured to generate a laser beam for coarse mechanical positioning of the antenna element;
an interferometer system comprising a plurality of antennas configured to receive signals from the antenna element for fine electrical positioning of the antenna element, the plurality of antennas including a removable center antenna, wherein the laser and the interferometer are collocated; and
a controller configured to control positioning of the laser and the interferometer based on information associated with the laser beam received by the controller and the signals received from the antenna element.

11. The system of claim 10, wherein:
the removable center antenna is configured to receive the signals from the antenna element to at least one of: measure polarization orientation of the received signals, measure relative group delay of the received signals, or measure radio frequency (RF) characteristics of the received signals;
the plurality of antennas comprises four antennas in equal-leg cruciform configuration; and
the center antenna is disposed at a centroid of the cruciform configuration.

12. The system of claim 11, wherein the controller is configured to:
determine whether the antenna element is mechanically aligned based on the generated laser beam; and
determine whether the antenna element is electrically aligned based on the signals received from the antenna element.

13. The system of claim 12, wherein, to determine whether the antenna element is mechanically aligned, the controller is configured to receive information associated with projection of the generated laser beam onto a target cover of the antenna element to determine misalignment of the antenna element.

14. The system of claim 12, wherein, to determine whether the antenna element is mechanically aligned, the controller is configured to receive information associated with light reflected by a mirror on the antenna element from projection of the generated laser beam to determine misalignment of the antenna element.

15. The system of claim 12, wherein, to determine whether the antenna element is electrically aligned, the controller is configured to calculate an angle of arrival of the signals received from the antenna element to determine attitude misalignment of the antenna element.

16. The system of claim 12, wherein, to determine whether the antenna element is electrically aligned, the controller is configured to calculate a relative group delay of the signals received from the antenna element to determine misalignment in an X-axis of the antenna element.

17. The system of claim 12, wherein, to determine whether the antenna element is electrically aligned, the controller is configured to calculate a polarization orientation of the signals received from the antenna element to determine roll misalignment of the antenna element.

18. The system of claim 12, wherein the controller is further configured to measure characteristics of the signals received from the antenna element to at least one of align, compensate, equalize, or verify elements of the signals received from the antenna element.

19. A method for testing an antenna element of an antenna array, the method comprising:
generating a laser beam;
receiving information associated with the laser beam for coarse mechanical positioning of the antenna element;
receiving, via an interferometer, signals from the antenna element for fine electrical positioning of the antenna element, wherein the laser and the interferometer are collocated; and
positioning the laser and the interferometer based on the received information associated with the laser beam and the signals received from the antenna element.

20. The method of claim 19, further comprising:
determining whether the antenna element is mechanically aligned based on the generated laser beam; and
determining whether the antenna element is electrically aligned based on the signals received from the antenna element.
